(19) United States
(12) Patent Application Publication
(10) Pub. No.: US 2020/0294895 A1
(43) Pub. Date: Sep. 17, 2020

(54) SEMICONDUCTOR DEVICE

(71) Applicants: KABUSHIKI KAISHA TOSHIBA, Minato-ku (JP); TOSHIBA ELECTRONIC DEVICES & STORAGE CORPORATION, Minato-ku (JP)

(72) Inventors: Hiroshi OHTA, Nonoichi (JP); Shunsuke NITTA, Hakusan (JP)

(73) Assignees: KABUSHIKI KAISHA TOSHIBA, Minato-ku (JP); TOSHIBA ELECTRONIC DEVICES & STORAGE CORPORATION, Minato-ku (JP)

(21) Appl. No.: 16/540,119

(22) Filed: Aug. 14, 2019

(30) Foreign Application Priority Data
Mar. 11, 2019 (JP) 2019-044014

(51) Int. Cl. H01L 23/495; H01L 23/31; H01L 23/492; H01L 23/00

(52) U.S. Cl. CPC H01L 23/49513; H01L 23/3135; H01L 2924/014; H01L 23/49541; H01L 24/29; H01L 23/492

(57) ABSTRACT

A semiconductor device includes a die pad; a semiconductor chip mounted on a front surface of the die pad; a bonding layer placed between the die pad and the semiconductor chip; a first resin member being positioned between the bonding layer and the semiconductor chip; and a second resin member covering the semiconductor chip and the front surface of the die pad. The first resin member is provided along a periphery of the semiconductor chip. The bonding layer includes a first portion and a second portion. The first portion is positioned between the semiconductor chip and the die pad, and contacts the semiconductor chip. The second portion is positioned between the first resin member and the die pad.

### CROSS-REFERENCE TO RELATED APPLICATIONS

This application is based upon and claims the benefit of priority from Japanese Patent Application No. 2019-044014, filed on Mar. 11, 2019; the entire contents of which are incorporated herein by reference.

### FIELD

Embodiments relate to a semiconductor device.

### BACKGROUND

There is a semiconductor device in which a semiconductor chip is mounted on a die pad and sealed in a resin package. Such a semiconductor device has a die pad shrinking in size corresponding to downsizing. When the die pad and the semiconductor chip are connected using a bonding member such as solder, the bonding member may extend around and cover an unintended portion of the die pad, thus, reducing air tightness of the resin package.

### BRIEF DESCRIPTION OF THE DRAWINGS

FIGS. 1A and 1B are schematic views showing a semiconductor device according to a first embodiment;

FIGS. 2A to 2C are schematic views showing a back surface of a semiconductor chip according to the first embodiment;

FIGS. 3A to 3C are schematic views showing a manufacturing process of the semiconductor device according to the first embodiment;

FIGS. 4A and 4B are schematic views showing a semiconductor device according to a second embodiment; and

FIGS. 5A to 5C are schematic views showing a manufacturing process of the semiconductor device according to the second embodiment.

### DETAILED DESCRIPTION

According to one embodiment, a semiconductor device includes a die pad; a semiconductor chip mounted on a front surface of the die pad; a bonding layer placed between the die pad and the semiconductor chip; a first resin member being positioned between the bonding layer and the semiconductor chip; and a second resin member covering the semiconductor chip and the front surface of the die pad. The first resin member is provided along a periphery of the semiconductor chip. The bonding layer includes a first portion and a second portion. The first portion is positioned between the semiconductor chip and the die pad, and contacts the semiconductor chip. The second portion is positioned between the first resin member and the die pad.

Embodiments will now be described with reference to the drawings. The same portions inside the drawings are marked with the same numerals; a detailed description is omitted as appropriate; and the different portions are described. The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

There are cases where the dispositions of the components are described using the directions of XYZ axes shown in the drawings. The X-axis, the Y-axis, and the Z-axis are orthogonal to each other. Hereinbelow, the directions of the X-axis, the Y-axis, and the Z-axis are described as an X-direction, a Y-direction, and a Z-direction. Also, there are cases where the Z-direction is described as upward and the direction opposite to the Z-direction is described as downward.

### First Embodiment

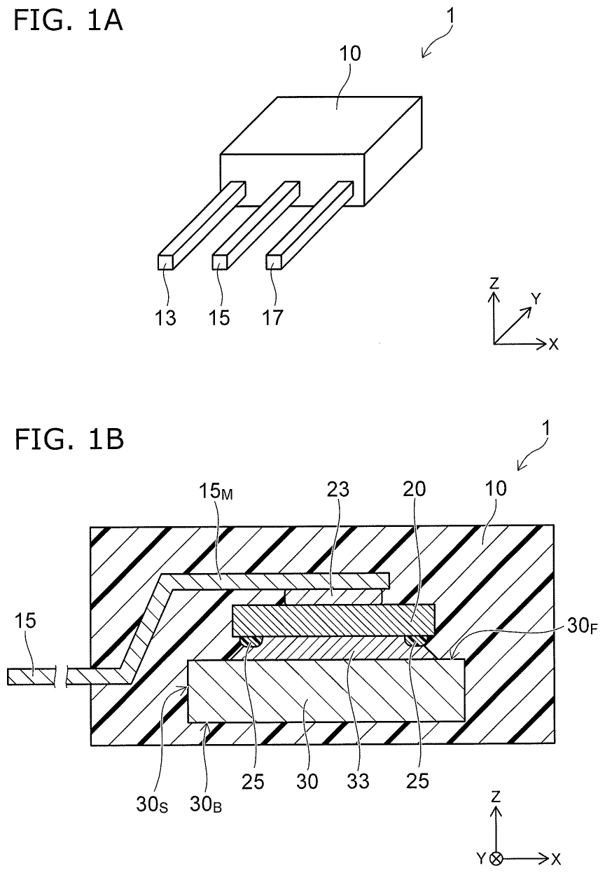

FIGS. 1A and 1B are schematic views showing a semiconductor device 1 according to a first embodiment. FIG. 1A is a perspective view showing an appearance of the semiconductor device 1. FIG. 1B is a schematic view showing a cross section parallel to a Y-Z plane. The semiconductor device 1 includes, for example, a MOSFET.

As shown in FIG. 1A, the semiconductor device 1 includes a resin package 10, and lead terminals 13, 15 and 17. The resin package 10 houses, for example, a semiconductor chip 20 (see FIG. 1B). The semiconductor chip 20 is, for example, a MOSFET chip.

The lead terminals 13, 15 and 17 are disposed, for example, so as to extend from one of side surfaces of the resin package 10. The lead terminal 13 is connected to, for example, the drain of the semiconductor chip 20, and the lead terminal 15 is connected to, for example, the source of the semiconductor chip 20. The lead terminal 17 is connected to, for example, the gate of the semiconductor chip 20. The lead terminals 13, 15 and 17 include, for example, copper or copper alloy.

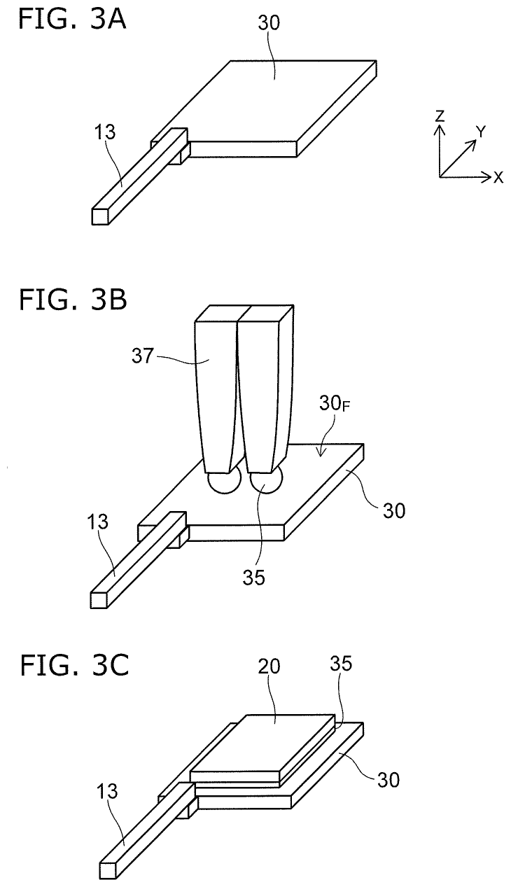

As shown in FIG. 1B, the semiconductor device 1 includes the semiconductor chip 20, a resin member 25, a die pad 30, and a connector 15_{M}. The die pad 30 is, for example, a lead type die pad including copper or copper alloy, and the lead terminal 13 is a portion of the die pad 30 (see FIG. 3A). The lead terminal 13 may be electrically connected to the die pad 30 by a metal wire (not shown). The lead terminal 15 is a portion of the connector 15_{M}.

The semiconductor chip 20 is mounted on a front surface 30_{F} of the die pad 30 via a bonding layer 33. A bonding layer 33 is, for example, a solder layer. The bonding layer 33 contacts, for example, a back electrode of the semiconductor chip 20, for example, a drain electrode (not shown), and electrically connects the semiconductor chip 20 and the die pad 30.

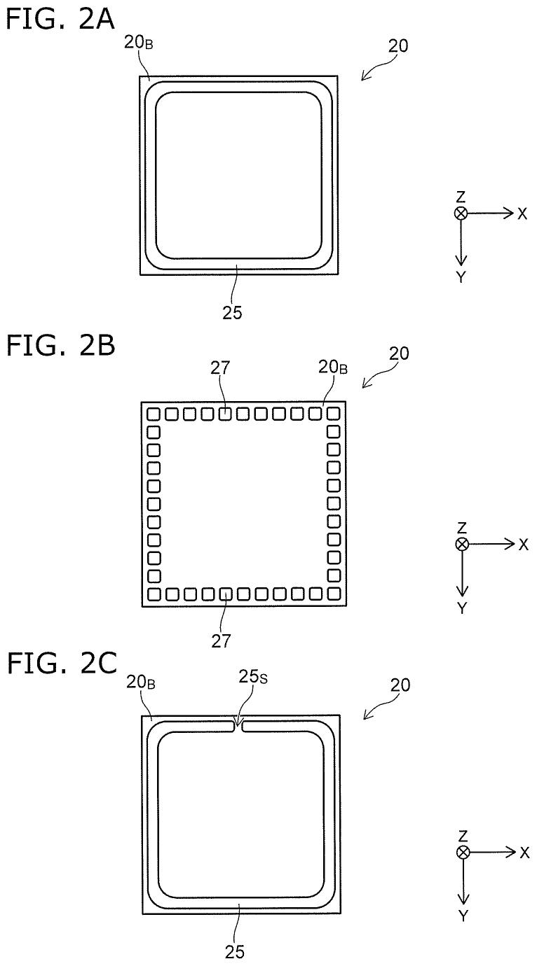

The resin member 25 is provided on a back surface side of the semiconductor chip 20. The resin member 25 is provided, for example, on the back electrode (the drain electrode) of the semiconductor chip 20. The resin member 25 is positioned between the semiconductor chip 20 and a portion of the bonding layer 33, and extends along a periphery of the semiconductor chip 20 (see FIG. 2A).

The connector 15_{M} is electrically connected via a bonding layer 23 to a front electrode of the semiconductor chip, for example, a source electrode (not shown). The connector 15_{M} is, for example, a metal plate including copper or cooper alloy. The bonding layer 23 is, for example, a solder layer.

The resin package 10 is provided to cover the semiconductor chip 20, the die pad 30 and the connector 15_{M}. The resin package 10 includes, for example, epoxy resin and is formed by a vacuum molding method.

As shown in FIG. 1B, the resin package 10 is provided to cover the front surface 30_{F}, a back surface 30_{B} and a side surface 30_{S} of the die pad 30. The semiconductor chip 20 is connected to an external circuit via the lead terminals 13, 15 and 17 that extend from the resin package 10. The lead terminal 17 is electrically connected to a gate pad (not shown) of the semiconductor chip 20 at a portion (not shown) in the resin package.

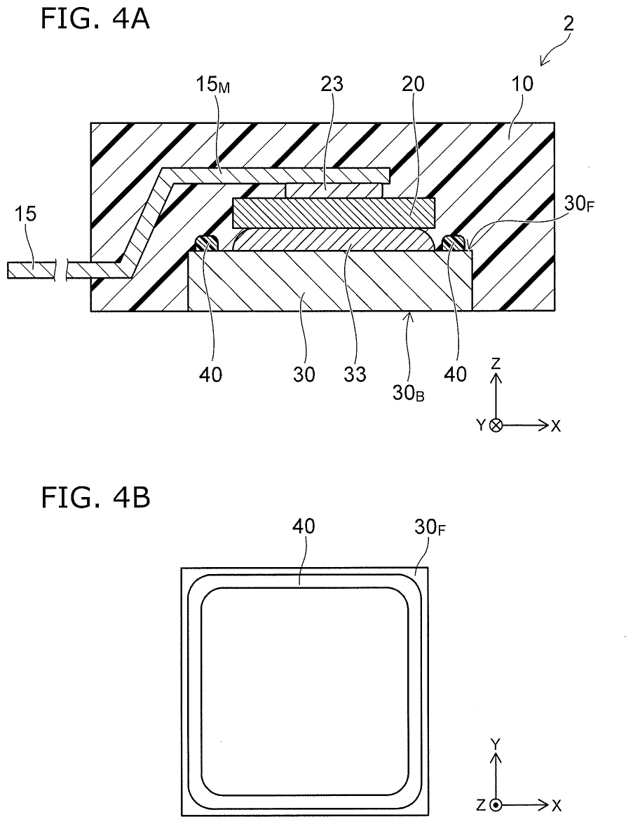

The embodiment is not limited to the above example. For example, there may be a configuration where the back surface 30_{B} of the die pad 30 is exposed at the resin package 10 (see FIG. 4A), and the lead terminal 13 electrically connected to the die pad 30 is omitted.

FIGS. 2A to 2C are schematic views showing the back surface 20_{B} of the semiconductor chip 20 according to the first embodiment. The back surface 20_{B} is, for example, a surface of the back electrode (the drain electrode).

As shown in FIG. 2A, the resin member 25 is provided on a back surface 20_{B} of the semiconductor chip 20. The resin member 25 is provided, for example, in a line shape along the periphery of the semiconductor chip 20. The resin member 25 is a member of one body extending continuously, and includes polyimide, for example.

The resin member 25 is formed in a predetermined shape by a photolithography after a resin film is formed on a back surface of the semiconductor wafer in a manufacturing process of the semiconductor chip 20.

As show in FIG. 2B, multiple resin members 27 are arranged on the back surface 20_{B} of the semiconductor chip 20. The resin members 27 may be provided in place of the resin member 25. The resin members 27 are spaced from each other along the periphery of the semiconductor chip 20. The resin members 27 include, for example, polyimide. The resin members 27 are formed, for example, using photolithography or a printing method.

As shown in FIG. 2C, a cutout portion 25S may be provided in the resin member 25. The cutout portion 25S is provided, for example, in a portion of the resin member 25 along at least one of four sides of the semiconductor chip 20 having the square shape. The resin member 25 may be formed, for example, by a printing method such as a screen printing. The resin member 25 in this example is suitable to be formed using a printing method.

A manufacturing method of the semiconductor device 1 will be described here with reference to FIGS. 3A to 3C. FIGS. 3A to 3C are schematic views showing in order the manufacturing process of the semiconductor device 1 according to the first embodiment.

As shown in FIG. 3A, a lead frame is prepared which includes a lead terminal 13 and a die pad 30. The die pad 30 is provided in a plurality, and the plurality of die pads 30 are arranged, for example, in the X-direction and the Y-direction. The die pad 30 is linked to a frame body (not shown) via the lead terminal 13.

As shown in FIG. 3B, a bonding member 35 is provided in drops on the front surface 30_{F} of the die pad 30. The bonding member 35 is, for example, liquid solder paste. For example, a predetermined amount of bonding member 35 falls in drops from a movable nozzle 37 on each of the plurality of die pads 30.

As shown in FIG. 3C, the semiconductor chip 20 is mounted on the front surface 30_{F} of the die pad 30 with the bonding member 35 interposed. The semiconductor chip 20 is mounted so that the back surface 20_{B} on which the resin member 25 is provided faces the die pad 30. Subsequently, heating the die pad 30 on which the semiconductor chip 20 is mounted is performed to convert the bonding member 35 to the bonding layer 33. The die pad 30 is heated, for example, through a reflow process of solder.

The bonding member 35 spreads in a space between the semiconductor chip 20 and the die pad 30, and contacts the back surface 20_{B} of the semiconductor chip 20 and the front surface 30_{F} of the die pad 30. Moreover, a portion of the bonding member 35 tends to spread outside the space between the semiconductor chip 20 and the die pad 30.

The resin member 25 includes, for example, a material having low affinity for the bonding member 35. Thus, the resin member 25 prevents the bonding member 35 from spreading outside the space. For example, the resin member 25 prevents the bonding member 35 from spreading outside the space at the contact portion of the resin member 25 and the bonding member 35 by a surface tension of the bonding member 35.

In the process shown in FIG. 3C, the amount of the bonding member 35 falling from the movable nozzle 37 is controlled at a level of filling the space between the semiconductor chip 20 and the die pad 30 and spreading into a space between the resin member 25 and the die pad 30 (see FIG. 1B). Thereby, it is possible to prevent the bonding member 35 from spreading outside the space between the semiconductor chip 20 and the die pad 30.

For example, in the case where the resin member 25 is not provided on the back surface 20_{B} of the semiconductor chip 20, when pressing force is applied to the semiconductor chip 20 toward the die pad 30 in order to form a uniform bonding layer between the semiconductor chi 20 and the die pad 30, the space is narrowed between the semiconductor chip 20 and the die pad 30. Thus, most of the bonding member 35 falling onto the die pad 30 is pushed out of the space between the semiconductor chip 20 and the die pad 30.

The amount of the bonding member 35 pushed out of the space depends on a case, for example, how the semiconductor chip 20 and the die pad 30 are bonded, and is not always the same. When the amount of the bonding member 35 pushed out of the space is large, the bonding member 35 spreads, for example, along the front surface 30_{F} of the die pad 30 through the process of heating the die pad 30, and may cover the side surface 30_{S} and the back surface 30_{B} (see FIG. 1). Thus, there may be a case, for example, where the electrodes disposed respectively on the front and back sides of the die pad 30 are short-circuited. Moreover, the adhesion strength may be reduced between the resin package 10 and the die pad 30, thereby, making the air tightness of the resin package 10 to be lowered. When the falling amount of the bonding member 35 is decreased to avoid such a case, a void space may be generated between the semiconductor chip 20 and the die pad 30, consequently reducing the reliability of the semiconductor device 1.

In contrast, in the semiconductor device 1 according to the embodiment, as the resin member 25 is provided on the back surface 20_{B} of the semiconductor chip 20, it is possible to secure the predetermined space between the semiconductor chip 20 and the die pad 30. Thereby, it is possible to hold a constant amount of bonding member 35 in the space between the semiconductor chip 20 and the die pad 30. Accordingly, the bonding member 35 may be provided with at least an amount being held in the space between the semiconductor chip 20 and the die pad 30. Thus, it is easy to control the falling amount of the bonding member 35 so that the void space is not generated between the semiconductor chip 20 and the die pad 30, and the bonding member 35 is not spread over the die pad 30 into the side surface 30_{S} and the back surface 30_{B}. In other words, it is possible to reduce the amount of the bonding member 35 pushed out the space between the semiconductor chip 20 and the die pad 30.

Furthermore, the resin member 25 prevents the bonding member 35 from spreading through the heating process of the die pad 30 with the semiconductor chip 20 mounted. As a result, it is possible to prevent the bonding member 35 from spreading into the side surface 30_{S} and the back surface 30_{B} and to improve the reliability of the semiconductor device 1.

In the case where the resin members 27 shown in FIG. 2B are used in place of the resin member 25, it is preferable to make a space width between the adjacent resin members 27 so that the bonding member 35 cannot pass therethrough. In other words, it is preferable to set the space width to prevent the resin members 27 from spreading outside through the space between the adjacent resin members 27 due to the surface tension of the bonding member 35.

### Second Embodiment

FIGS. 4A and 4B are schematic views showing a semiconductor device 2 according to a second embodiment. FIG. 4A is a schematic view showing a cross section parallel to the X-Z plane. FIG. 4B is a plan view showing a resin member 40 provided on the front surface of the die pad 30.

As shown in FIG. 4A, the semiconductor chip 20 is mounted on the die pad 30 with the bonding layer 33 interposed. Moreover, the connector 15_{M} is bonded on the semiconductor chip 20 with the bonding layer 23 interposed.

In the embodiment, the resin member 40 is disposed on the front surface 30_{F} of the die pad 30. The resin package 10 is molded so that the back surface 30_{B} of the die pad 30 is exposed. The embodiment is not limited to this example. For example, the resin package 10 may be formed so as to cover the whole surface of the die pad 30 (see FIG. 1B).

As shown in FIG. 4B, the resin member 40 is, for example, provided with a line shape along the periphery of the die pad 30. There may be a case where the resin member 40 is provided in a plurality along the periphery of the die pad 30 (see FIG. 2B). The resin member 40 is provided outside a region on which the semiconductor chip 20 is mounted, and is not placed between the semiconductor chip 20 and the die pad 30.

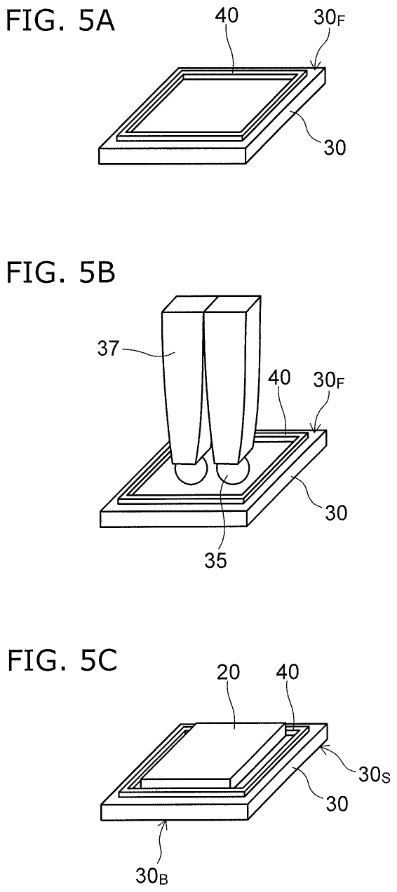

A manufacturing method of the semiconductor device 2 will be described here with reference to FIGS. 5A to 5C. FIGS. 5A to 5C are schematic views showing in order the manufacturing process of the semiconductor device 2 according to the second embodiment.

As shown in FIG. 5A, the resin member 40 is formed on the front surface 30_{F} of the die pad 30. The resin member 40 is selectively formed, for example, using a printing method or an inkjet method. The resin member 40 is not formed on the region of the front surface 30_{F} on which the semiconductor chip 20 is to be mounted.

As shown in FIG. 5B, the bonding member 35 falls in drops on the front surface 30_{F} of the die pad 30. The bonding member 35 is, for example, liquid solder paste. The bonding member 35 falls on a region surrounded by the resin member 40.

As shown in FIG. 5C, the semiconductor chip 20 is mounted on the front surface 30_{F} of the die pad 30 with the bonding member 35 interposed. Then, the die pad 30 on which the semiconductor chip 20 is mounted is heated to convert the bonding member 35 to the bonding layer 33.

The resin member 40 serves as a blocking bank preventing the bonding member 35 from spreading over the front surface 30_{F} of the die pad 30. Thereby, it is possible to prevent the bonding member 35 from spreading over the die pad 30 into the side surface 30_{S} and the back surface 30_{B}, and to improve the reliability of the semiconductor device 2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a die pad;
a semiconductor chip mounted on a front surface of the die pad;
a bonding layer placed between the die pad and the semiconductor chip;
a first resin member being positioned between the bonding layer and the semiconductor chip, the first resin member being provided along a periphery of the semiconductor chip; and
a second resin member covering the semiconductor chip and the front surface of the die pad,
the bonding layer including a first portion part and a second portion, the first portion being positioned between the semiconductor chip and the die pad and contacting the semiconductor chip, the second portion being positioned between the first resin member and the die pad.

2. The device according to claim 1, wherein the bonding layer fill a space between the semiconductor chip and the die pad, the space being surrounded by the first resin member.

3. The device according to claim 1, wherein the second portion of the bonding layer contacts the first resin member.

4. The device according to claim 1, wherein the first resin member includes a material different from a material of the second resin member.

5. The device according to claim 1, wherein the first resin member includes a material having low affinity for the bonding layer.

6. The device according to claim 1, wherein the first resin member includes polyimide.

7. The device according to claim 1, further comprising:
a first connection conductor electrically connected to the semiconductor chip, the first connection conductor including a first portion and a second portion, the first portion of the first connection conductor extending in the second resin member, the second portion of the first connection conductor extending outside the second resin member.

8. The device according to claim 1, wherein the second resin member covers surfaces of the die pad other than a back surface.

9. The device according to claim 1, wherein the second resin member covers whole surfaces of the die pad.

10. The device according to claim 8, further comprising:
a second connection conductor electrically connected to the die pad, the second connection conductor including a portion extending outside the second resin member.

11. The device according to claim 1, wherein the first resin member is provided in a plurality, the plurality of first resin members being arranged along the periphery of the semiconductor chip and being spaced from each another.

12. The device according to claim 1, wherein the first resin member has a cutout portion.

13. The device according to claim 1, wherein the first resin member has a continuous body.

14. A semiconductor device, comprising:
a die pad;
a semiconductor chip mounted on a front surface of the die pad;
a bonding layer placed between the die pad and the semiconductor chip;
a first resin member provided along an outer edge of the front surface of the die pad, the first resin member surrounding the semiconductor chip and the bonding layer; and
a second resin member covering the semiconductor chip and the front surface of the die pad,
the first resin member including no portion positioned between the die pad and the semiconductor chip.
